(19) United States
(12) Patent Application Publication
(10) Pub. No.: US 2026/0231502 A1
(43) Pub. Date: Aug. 6, 2026

(54) INTEGRATED CIRCUIT DEVICES INCLUDING A CONTACT STRUCTURE AND METHODS OF FORMING THE SAME

(71) Applicant: Samsung Electronics Co., Ltd., Suwon-si (KR)

(72) Inventors: Wonkeun Chung, Clifton Park, NY (US); Byounghoon Kim, Rexford, NY (US); Sangshin Jang, Rexford, NY (US); Kang-ill Seo, Springfield, VA (US)

(21) Appl. No.: 19/259,632

(22) Filed: Jul. 3, 2025

Related U.S. Application Data
(60) Provisional application No. 63/750,891, filed on Jan. 29, 2025.

(51) Int. Cl. H10D 64/23; H10D 30/00; H10D 84/01; H10D 84/83; H10W 20/40; H10W 20/41

(52) U.S. Cl. CPC H10D 64/251; H10D 30/502; H10D 84/0149; H10D 84/832; H10W 20/435; H10W 20/498

(57) ABSTRACT

An integrated circuit device includes a substrate having a contact opening and a contact in the contact opening. A first portion of the contact has a first width in a first direction that is parallel with an upper surface of the substrate. A second portion of the contact has a second width in the first direction. A third portion of the contact has a third width in the first direction. The second portion of the contact is between the first portion of the contact and the third portion of the contact in a second direction that is perpendicular to the upper surface of the substrate. At least one of the first width and the third width is greater than the second width. Another of the first width and the third width is equal to or greater than the second width.

### CROSS-REFERENCE TO RELATED APPLICATIONS

This application claims priority to U.S. Provisional Application Serial No. 63/750,891 entitled INTEGRATED CIRCUIT DEVICES INCLUDING LOW RESISTANCE CONTACT PROFILES WITH IMPROVED SHORT MARGIN AND METHODS OF FORM I NG THE SAME,filed in the USPTO on January 29, 2025, the disclosure of which is hereby incorporated by reference herein in its entirety.

### TECHNICAL FIELD

The present disclosure generally relates to the field of integrated circuit devices and, more particularly, to integrated circuit devices including a conductive element, such as a contact.

Various structures of an integrated circuit device and methods of forming the same have been proposed to increase the integration density of the integrated circuit device. Specifically, various structures of an integrated circuit device and methods of forming the same have been proposed to reduce critical dimension (CD) between conductive elements, such as patterns and contacts, without short circuits while reducing the resistance of the conductive elements.

### SUMMARY

An aspect of the present disclosure is to provide integrated circuit devices having a contact with improved (reduced) CD and resistance by modifying the profile of the contact. However, it will be understood that the embodiments, goals, and benefits of the present disclosure are not limited to the descriptions above.

According to some embodiments, an integrated circuit device includes a substrate that has a contact opening; and a contact in the contact opening, wherein a first portion of the contact has a first width in a first direction that is parallel with an upper surface of the substrate, wherein a second portion of the contact has a second width in the first direction, wherein a third portion of the contact has a third width in the first direction, wherein the second portion of the contact is between the first portion of the contact and the third portion of the contact in a second direction that is perpendicular to the upper surface of the substrate, wherein at least one of the first width and the third width is greater than the second width, and wherein another of the first width and the third width is equal to or greater than the second width.

According to some embodiments, an integrated circuit device includes a substrate that has a contact opening; spacers on sidewalls of the contact opening in the substrate in a cross-sectional view, wherein the spacers are spaced apart from each other in a first direction that is parallel with an upper surface of the substrate; and a contact between the spacers in the first direction, wherein first portions of the spacers are spaced apart from each other at a first distance in the first direction, wherein second portions of the spacers are spaced apart from each other at a second distance in the first direction, and wherein third portions of the spacers are spaced apart from each other at a third distance in the first direction, wherein the second portions are between the first portions and the third portions in a second direction that is perpendicular to the upper surface of the substrate, wherein at least one of the first distance and the third distance is greater than the second distance, and wherein another of the first distance and the third distance is equal to or greater than the second distance.

According to some embodiments, a method of forming an integrated circuit device includes forming a contact opening in a substrate, the contact opening having opposing sidewalls and a lower surface therebetween; performing a surface treatment on the lower surface of the contact opening; forming a spacer on at least one of the opposing sidewalls of the contact opening; and forming a contact on the spacer in the contact opening, wherein the forming the spacer comprises a selective growth on a side surface of the substrate exposed by the contact opening.

### BRIEF DESCRIPTION OF THE DRAWINGS

FIGS. 1A and 1B are cross-sectional views of an integrated circuit device according to some embodiments.

FIGS. 2A and 2B are cross-sectional views of an integrated circuit device according to some embodiments.

FIGS. 3A and 3B are cross-sectional views of an integrated circuit device according to some embodiments.

FIGS. 4A and 4B are cross-sectional views of an integrated circuit device according to some embodiments.

FIG. 5 is a flow chart of methods of forming an integrated circuit device according to some embodiments.

FIGS. 6A, 6B, 7A, 7B, 8A, 8B, 9A, and 9B are cross-sectional views, illustrating methods of forming an integrated circuit device in FIGS. 3A and 3B according to some embodiments. FIGS. 6A and 6B are cross-sectional views of an intermediate process, including forming a contact opening in a substrate. FIGS. 7A and 7B are cross-sectional views of an intermediate process, including treating a surface of a substrate (e.g., a surface of the substrate exposed by the contact opening) to form a treated layer. FIGS. 8A and 8B are cross-sectional views of an intermediate process, including forming a spacer on an untreated surface of the substrate (in the contact opening). FIGS. 9A and 9B are cross-sectional views of an intermediate process, including removing the treated layer.

FIG. 10 is a cross-sectional view an integrated circuit device according to some embodiments.

FIG. 11 is a cross-sectional view an integrated circuit device according to some embodiments.

### DETAILED DESCRIPTION

According to aspects of the current disclosure, a contact may have a first portion (e.g., a lower portion) with a first width, a second portion (e.g., a middle portion) with a second width, and a third portion (e.g., an upper portion) with a third width. In some embodiments, the first width may be equal to or greater than the second width, and the third width may be equal to or greater than the second width. In some embodiments, at least one of the first width and the third width may be greater than the second width. Example embodiments will be described in greater detail with reference to the attached figures.

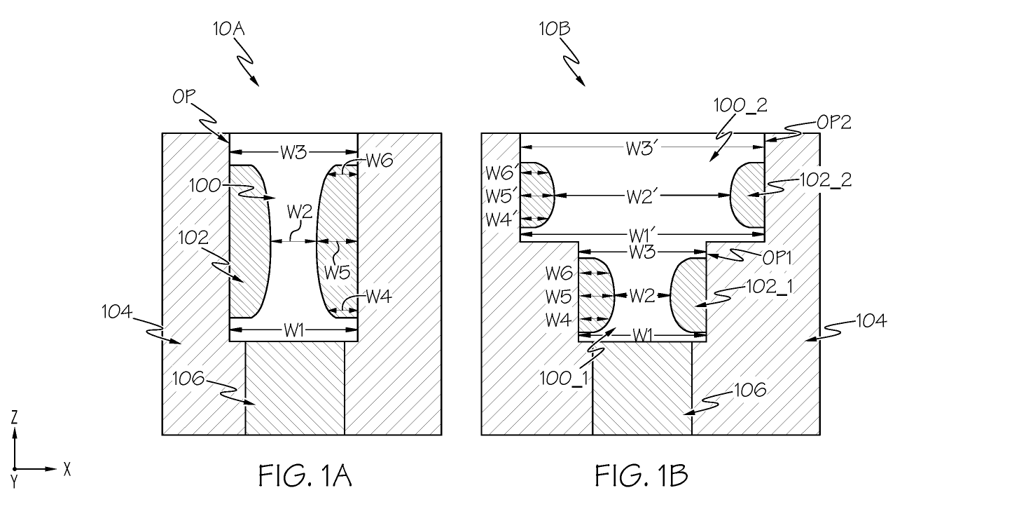

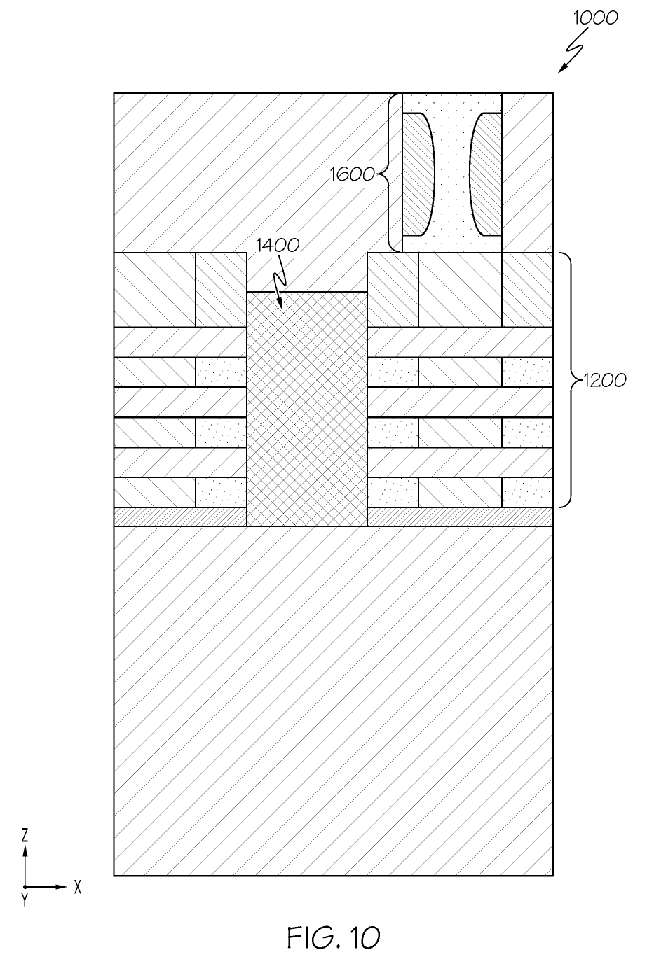

FIGS. 1A and 1B are cross-sectional views of integrated circuit devices 10A and 10B, respectively, according to some embodiments. The integrated circuit device 10A may include a substrate 104 that includes a device element 106. The substrate 104 may include semiconductor material(s), for example, Si, Ge, SiGe, GaP, GaAs, SiC, SiGeC and/or InP and/or may include insulating material(s), for example, silicon oxide, silicon oxynitride, silicon nitride, silicon carbonitride and/or a low-k material. In some embodiments, the substrate 104 may be a bulk substrate (e.g., a silicon wafer), a semiconductor on insulator (SOI) substrate or an insulating layer (e.g., a monolithic insulating layer). Herein, the low-k material may be a material having a dielectric constant lower than that of silicon oxide. The low-k material may include, for example, SiCOH, fluorine-doped silicon oxide, organosilicate glass, carbon-doped oxide, porous silicon dioxide, porous organosilicate glass, spin-on organic polymeric dielectrics and/or spin-on silicon based polymeric dielectric. The device element 106 may be, for example, a gate structure (refer to a gate structure 1200 in FIG. 10) or a source/drain (S/D) region (refer to a source/drain (S/D) region 1400 in FIG. 10), but the embodiments of the device element 106 are not limited thereto. For example, the device element 106 may be a portion of the substrate 104. A contact 100 may be electrically connected to (may be in contact with) the device element 106.

Referring to FIG. 1A, the substrate 104 may have a contact opening OP. The contact opening OP may extend into the substrate 104. For example, the contact opening OP may extend into the substrate 104 in a first direction that is perpendicular to an upper surface (and/or a lower surface) of the substrate 104 (e.g., Z-direction). In some embodiments, the contact opening OP may expose a portion of the substrate 104 and/or a portion of the device element 106. For example, a sidewall of the contact opening OP may expose (correspond to) a side surface of the substrate 104. A lower end of the contact opening OP may expose (correspond to) an upper surface of the device element 106. However, the embodiments herein are not limited thereto.

Referring to FIG. 1A, the integrated circuit device 10A may include the contact 100 in the contact opening OP. In some embodiments, the contact 100 may partially fill the contact opening OP. The contact 100 may include, for example, a conductive material, such as metal. For example, the contact 100 may include Ru, Mo, W, Cu, and/or Al, but the embodiments are not limited thereto.

The contact 100 may have a first portion, a second portion, and a third portion. In some embodiments, the first portion of the contact 100 may be closer (closer than the second portion of the contact 100 and the third portion of the contact 100) to the device element 106, and the third portion of the contact 100 may be farther (farther than the first portion of the contact 100 and the second portion of the contact 100) from the device element 106. The second portion of the contact 100 may be between the first portion of the contact 100 and the third portion of the contact 100 in the first direction. For example, the first portion of the contact 100 may be a lower portion of the contact 100, the second portion of the contact 100 may be a middle portion of the contact 100, and the third portion of the contact 100 may be an upper portion of the contact 100.

The first portion of the contact 100 may have a first width W1 in a second direction that is parallel with the upper surface (and/or the lower surface) of the substrate 104 (e.g., X-direction), the second portion of the contact 100 may have a second width W2 in the second direction, and the third portion of the contact 100 may have a third width W3 in the second direction. In some embodiments, the first width W1 may be equal to or greater than the second width W2, and the third width W3 may be equal to or greater than the second width W2. For example, at least one of the first width W1 and the third width W3 may be greater than the second width W2. For example, at least one of the first width W1 and the third width W3 may be greater than the second width W2, and another of the first width W1 and the third width W3 may be equal to or greater than the second width W2. In some embodiments, the contact 100 may have an hourglass shape in a cross-sectional view.

The integrated circuit device 10A may further include a spacer 102 in the contact opening OP. In some embodiments, the spacer 102 may include an insulating material, such as SiO, SiON, and/or SiCN, but the embodiments are not limited thereto. The spacer 102 may be on a sidewall of the contact opening OP. For example, the spacer 102 may be on (e.g., in contact with or grown from) a side surface of the substrate 104 exposed by the contact opening OP.

The spacer 102 may have a first portion, a second portion, and a third portion. In some embodiments, the first portion of the spacer 102 may be closer (closer than the second portion of the spacer 102 and the third portion of the spacer 102) to the device element 106, and the third portion of the spacer 102 may be farther (farther than the first portion of the spacer 102 and the second portion of the spacer 102) from the device element 106. The second portion of the spacer 102 may be between the first portion of the spacer 102 and the third portion of the spacer 102 in the first direction. For example, the first portion of the spacer 102 may be a lower portion of the spacer 102, the second portion of the spacer 102 may be a middle portion of the spacer 102, and the third portion of the spacer 102 may be an upper portion of the spacer 102.

The first portion of the spacer 102 may have a fourth width W4 in the second direction, the second portion of the spacer 102 may have a fifth width W5 in the second direction, and the third portion of the spacer 102 may have a sixth width W6 in the second direction. In some embodiments, the fourth width W4 may be equal to or less than the fifth width W5, and the sixth width W6 may be equal to or less than the fifth width W5. For example, at least one of the fourth width W4 and the sixth width W6 may be less than the fifth width W5. For example, at least one of the fourth width W4 and the sixth width W6 may be less than the fifth width W5, and another of the fourth width W4 and the sixth width W6 may be equal to or less than the fifth width W5. In some embodiments, the spacer 102 may have a convex shape protruding from the sidewall of the contact opening OP (from the side surface of the substrate 104 exposed by the contact opening OP) (in the second direction).

In some embodiments, the contact 100 may be on an upper surface (an upper end) of the spacer 102. In some embodiments, the contact 100 may be on a lower surface (a lower end) of the spacer 102.

In some embodiments, in a cross-sectional view, spacers 102 that are opposite to each other in the second direction may be on the sidewalls of the contact opening OP that are opposite to each other in the second direction (e.g., the side surfaces of the substrate 104 that are opposite to each other in the second direction and exposed by the contact opening OP). In some embodiments, the spacers 102 may be mirror-symmetric to each other in the second direction. The contact 100 may be between the spacers 102 in the second direction.

The first portions (e.g., the lower portions) of the spacers 102 may be spaced apart from each other at a first distance in the second direction. The second portions (e.g., the middle portions) of the spacers 102 may be spaced apart from each other at a second distance in the second direction. The third portions (e.g., the upper portions) of the spacers 102 may be spaced apart from each other at a third distance in the second direction. In some embodiments, the first distance may be equal to or greater than the second distance. The third distance may be equal to or greater than the second distance. For example, at least one of the first distance and the third distance may be greater than the second distance. For example, at least one of the first distance and the third distance may be greater than the second distance, and another of the first distance and the third distance may be equal to or greater than the second distance. In some embodiments, the first distance may be equal to the first width W1 of the contact 100, the second distance may be equal to the second width W2 of the contact 100, and the third distance may be equal to the third width W3 of the contact 100, but the embodiments are not limited thereto.

Referring to FIG. 1B, the substrate 104 may include a first contact opening OP1 and a second contact opening OP2 on the first contact OP1. The first contact opening OP1 and the second contact opening OP2 may be integrated as a greater contact opening. FIG. 1B illustrates two contact openings stacked in the first direction, but the numbers and arrangements of the contact openings are not limited thereto. The example embodiments described in FIG. 1B may be configured the same as or (substantially) similar to the example embodiments described with reference to FIG. 1A, other than the configuration in which the first contact opening OP1 and the second contact opening OP2 are integrated as a greater contact opening. For example, a first contact (e.g., a lower contact) 100_1 may be in the first contact opening OP1, and a second contact (e.g., an upper contact) 100_2 may be in the second contact opening OP2. The first contact 100_1 and the second contact 100_2 may be integrated with each other as a monolithic contact structure. A monolithic structure (e.g., the monolithic contact structure) herein may refer to a structure (e.g., a continuum) without a (visible) boundary between its sub-structures (e.g., the first contact 100_1 and the second contact 100_2).

The first contact 100_1 may have a first portion, a second portion, and a third portion. In some embodiments, the first portion of the first contact 100_1 may be closer (closer than the second portion of the first contact 100_1 and the third portion of the first contact 100_1) to the device element 106, and the third portion of the first contact 100_1 may be farther (farther than the first portion of the first contact 100_1 and the second portion of the first contact 100_1) from the device element 106. The second portion of the first contact 100_1 may be between the first portion of the first contact 100_1 and the third portion of the first contact 100_1 in the first direction. For example, the first portion of the first contact 100_1 may be a lower portion of the first contact 100_1, the second portion of the first contact 100_1 may be a middle portion of the first contact 100_1, and the third portion of the first contact 100_1 may be an upper portion of the first contact 100_1.

The first portion of the first contact 100_1 may have a first width W1 in the second direction, the second portion of the first contact 100_1 may have a second width W2 in the second direction, and the third portion of the first contact 100_1 may have a third width W3 in the second direction. In some embodiments, the first width W1 may be equal to or greater than the second width W2, and the third width W3 may be equal to or greater than the second width W2. For example, at least one of the first width W1 and the third width W3 may be greater than the second width W2. For example, at least one of the first width W1 and the third width W3 may be greater than the second width W2, and another of the first width W1 and the third width W3 may be equal to or greater than the second width W2.

The second contact 100_2 may have a first portion, a second portion, and a third portion. In some embodiments, the first portion of the second contact 100_2 may be closer (closer than the second portion of the second contact 100_2 and the third portion of the second contact 100_2) to the device element 106, and the third portion of the second contact 100_2 may be farther (farther than the first portion of the second contact 100_2 and the second portion of the second contact 100_2) from the device element 106. The second portion of the second contact 100_2 may be between the first portion of the second contact 100_2 and the third portion of the second contact 100_2 in the first direction. For example, the first portion of the second contact 100_2 may be a lower portion of the second contact 100_2, the second portion of the second contact 100_2 may be a middle portion of the second contact 100_2, and the third portion of the second contact 100_2 may be an upper portion of the second contact 100_2.

The first portion of the second contact 100_2 may have a first width W1' in the second direction, the second portion of the second contact 100_2 may have a second width W2' in the second direction, and the third portion of the second contact 100_2 may have a third width W3' in the second direction. In some embodiments, the first width W1' may be equal to or greater than the second width W2', and the third width W3' may be equal to or greater than the second width W2'. For example, at least one of the first width W1' and the third width W3' may be greater than the second width W2'. For example, at least one of the first width W1' and the third width W3' may be greater than the second width W2', and another of the first width W1' and the third width W3' may be equal to or greater than the second width W2'.

The integrated circuit device 10B may include a first spacer 102_1 in the first contact opening OP_1. The first spacer 102_1 may be on a sidewall of the first contact opening OP_1. For example, the first spacer 102_1 may be on (e.g., in contact with or grown from) a side surface of the substrate 104 exposed by the first contact opening OP_1.

The first spacer 102_1 may have a first portion, a second portion, and a third portion. In some embodiments, the first portion of the first spacer 102_1 may be closer (closer than the second portion of the first spacer 102_1 and the third portion of the first spacer 102_1) to the device element 106, and the third portion of the first spacer 102_1 may be farther (farther than the first portion of the first spacer 102_1 and the second portion of the first spacer 102_1) from the device element 106. The second portion of the first spacer 102_1 may be between the first portion of the first spacer 102_1 and the third portion of the first spacer 102_1 in the first direction. For example, the first portion of the first spacer 102_1 may be a lower portion of the first spacer 102_1, the second portion of the first spacer 102_1 may be a middle portion of the first spacer 102_1, and the third portion of the first spacer 102_1 may be an upper portion of the first spacer 102_1.

The first portion of the first spacer 102_1 may have a fourth width W4 in the second direction, the second portion of the first spacer 102_1 may have a fifth width W5 in the second direction, and the third portion of the first spacer 102_1 may have a sixth width W6 in the second direction. In some embodiments, the fourth width W4 may be equal to or less than the fifth width W5, and the sixth width W6 may be equal to or less than the fifth width W5. For example, at least one of the fourth width W4 and the sixth width W6 may be less than the fifth width W5. For example, at least one of the fourth width W4 and the sixth width W6 may be less than the fifth width W5, and another of the fourth width W4 and the sixth width W6 may be equal to or less than the fifth width W5. In some embodiments, the first spacer 102_1 may have a convex shape protruding from the sidewall of the first contact opening OP_1 (or the side surface of the substrate 104 exposed by the first contact opening OP_1) (in the second direction).

The integrated circuit device 10B may further include a second spacer 102_2 in the second contact opening OP_2. The second spacer 102_2 may be on a sidewall of the second contact opening OP_2. For example, the second spacer 102_2 may be on (e.g., in contact with or grown from) a side surface of the substrate 104 exposed by the second contact opening OP_2.

The second spacer 102_2 may have a first portion, a second portion, and a third portion. In some embodiments, the first portion of the second spacer 102_2 may be closer (closer than the second portion of the second spacer 102_2 and the third portion of the second spacer 102_2) to the device element 106, and the third portion of the second spacer 102_2 may be farther (farther than the first portion of the second spacer 102_2 and the second portion of the second spacer 102_2) from the device element 106. The second portion of the second spacer 102_2 may be between the first portion of the second spacer 102_2 and the third portion of the second spacer 102_2 in the first direction. For example, the first portion of the second spacer 102_2 may be a lower portion of the second spacer 102_2, the second portion of the second spacer 102_2 may be a middle portion of the second spacer 102_2, and the third portion of the second spacer 102_2 may be an upper portion of the second spacer 102_2.

The first portion of the second spacer 102_2 may have a fourth width W4' in the second direction, the second portion of the second spacer 102_2 may have a fifth width W5' in the second direction, and the third portion of the second spacer 102_2 may have a sixth width W6' in the second direction. In some embodiments, the fourth width W4' may be equal to or less than the fifth width W5', and the sixth width W6' may be equal to or less than the fifth width W5'. For example, at least one of the fourth width W4' and the sixth width W6' may be less than the fifth width W5'. For example, at least one of the fourth width W4' and the sixth width W6' may be less than the fifth width W5', and another of the fourth width W4' and the sixth width W6' may be equal to or less than the fifth width W5'. In some embodiments, the second spacer 102_2 may have a convex shape protruding from the sidewall of the second contact opening OP_2 (or the side surface of the substrate 104 exposed by the second contact opening OP_2) (in the second direction).

In some embodiments, the first contact 100_1 may be on an upper surface (an upper end) of the first spacer 102_1. In some embodiments, the first contact 100_1 may be on a lower surface (a lower end) of the first spacer 102_1. In some embodiments, the second contact 100_2 may be on an upper surface (an upper end) of the second spacer 102_2. In some embodiments, the second contact 100_2 may be on a lower surface (a lower end) of the second spacer 102_2.

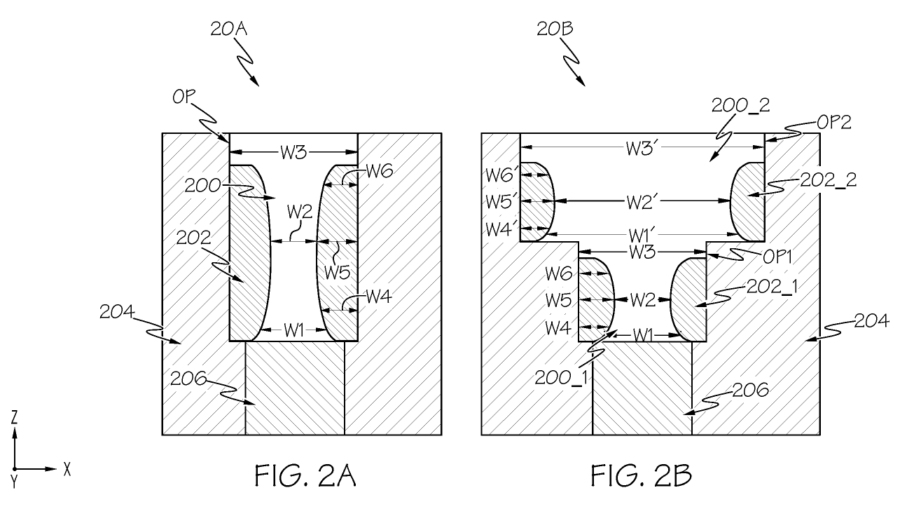

FIGS. 2A and 2B are cross-sectional views of integrated circuit devices 20A and 20B, respectively, according to some embodiments.

The contact opening OP, the contact 200, the spacer 202, the substrate 204, and the device element 206 in FIG. 2A may correspond to the contact opening OP, the contact 100, the spacer 102, the substrate 104, and the device element 106 in FIG. 1A, respectively. The first contact opening OP1, the second contact opening OP2, the first contact 200_1, the second contact 200_2, the first spacer 202_1, the second spacer 202_2, the substrate 204, and the device element 206 in FIG. 2B may correspond to the first contact opening OP1, the second contact opening OP2, the first contact 100_1, the second contact 100_2, the first spacer 102_1, the second spacer 102_2, the substrate 104, and the device element 106 in FIG. 1B, respectively.

The example embodiments described in FIG. 2A may be configured the same as or (substantially) similar to the example embodiments described with reference to FIG. 1A, other than the configuration in which the lower surface (e.g., the lower end) of the spacer 202 may be coplanar with a lower surface of the contact 200. In some embodiments, the lower surface of the contact 200 and the lower surface (e.g., the lower end) of the spacer 202 may be at a lower end (e.g., bottom end) of the contact opening OP. For example, the contact 200 and the spacer 202 may be in contact with an upper surface of the device element 206 and/or a lower surface of the substrate 204 exposed by (the lower end of) the contact opening OP.

The example embodiments described in FIG. 2B may be configured the same as or (substantially) similar to the example embodiments described with reference to FIG. 1B, other than the configuration in which the lower surface (e.g., the lower end) of the first spacer 202_1 may be coplanar with a lower surface of the first contact 200_1, and the lower surface (e.g., the lower end) of the second spacer 202_2 may be coplanar with a lower surface of the second contact 200_2. In some embodiments, the lower surface of the first contact 200_1 and the lower surface (e.g., the lower end) of the first spacer 202_1 may be at a lower end (e.g., the bottom end) of the first contact opening OP1. For example, the first contact 200_1 and the first spacer 202_1 may be in contact with an upper surface of the device element 206 and/or a lower surface of the substrate 204 exposed by (the lower end of) the first contact opening OP1. In some embodiments, the lower surface of the second contact 200_2 and the lower surface (e.g., the lower end) of the second spacer 202_2 may be at a lower end (e.g., the bottom end) of the second contact opening OP2. For example, the second contact 200_2 and the second spacer 202_2 may be in contact with an upper surface of the first contact 200_1 and/or a lower surface of the substrate 204 exposed by (the lower end of) the second contact opening OP2.

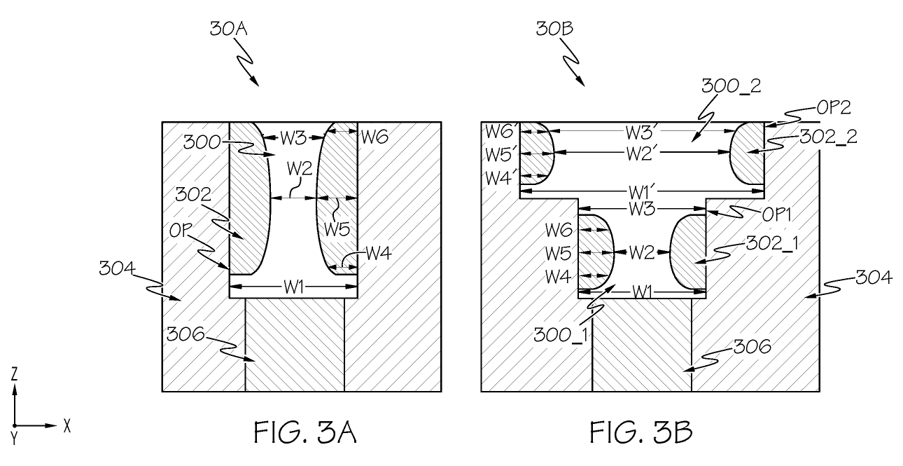

FIGS. 3A and 3B are cross-sectional views of integrated circuit devices 30A and 30B, respectively, according to some embodiments.

The contact opening OP, the contact 300, the spacer 302, the substrate 304, and the device element 306 in FIG. 3A may correspond to the contact opening OP, the contact 100, the spacer 102, the substrate 104, and the device element 106 in FIG. 1A, respectively. The first contact opening OP1, the second contact opening OP2, the first contact 300_1, the second contact 300_2, the first spacer 302_1, the second spacer 302_2, the substrate 304, and the device element 306 in FIG. 3B may correspond to the first contact opening OP1, the second contact opening OP2, the first contact 100_1, the second contact 100_2, the first spacer 102_1, the second spacer 102_2, the substrate 104, and the device element 106 in FIG. 1B, respectively.

The example embodiments described in FIG. 3A may be configured the same as or (substantially) similar to the example embodiments described with reference to FIG. 1A, other than the configuration in which an upper surface (e.g., an upper end) of the spacer 302 may be coplanar with an upper surface of the contact 300. In some embodiments, the upper surface of the contact 300 and the upper surface (e.g., the upper end) of the spacer 302 may be at an upper end (e.g., the top end) of the contact opening OP. For example, the upper surface of the contact 300 and the upper surface (e.g., the upper end) of the spacer 302 may be coplanar with the upper surface of the substrate 304. In some embodiments, a width in the second direction of the upper end (e.g., the top end) of the contact opening OP may be equal to the third width W3 of the third portion of the contact 300.

The example embodiments described in FIG. 3B may be configured the same as or (substantially) similar to the example embodiments described with reference to FIG. 1B, other than the configuration in which the upper surface (e.g., the upper end) of the second spacer 302_2 may be coplanar with an upper surface of the second contact 300_2. In some embodiments, the upper surface of the second contact 300_2 and the upper surface (e.g., the upper end) of the second spacer 302_2 may be at an upper end (e.g., the top end) of the second contact opening OP2. For example, the upper surface of the second contact 300_2 and the upper surface (e.g., the upper end) of the second spacer 302_2 may be coplanar with the upper surface of the substrate 304. In some embodiments, a width in the second direction of the upper end (e.g., the top end) of the second contact opening OP2 may be equal to the third width W3' of the third portion of the second contact 300_2.

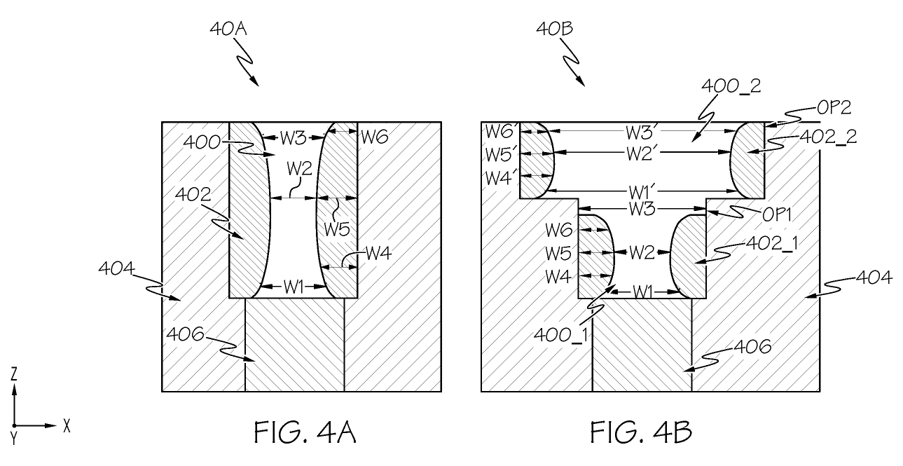

FIGS. 4A and 4B are cross-sectional views of integrated circuit devices 40A and 40B, respectively, according to some embodiments.

The contact opening OP, the contact 400, the spacer 402, the substrate 404, and the device element 406 in FIG. 4A may correspond to the contact opening OP, the contact 100, the spacer 102, the substrate 104, and the device element 106 in FIG. 1A, respectively. The first contact opening OP1, the second contact opening OP2, the first contact 400_1, the second contact 400_2, the first spacer 402_1, the second spacer 402_2, the substrate 404, and the device element 406 in FIG. 4B may correspond to the first contact opening OP1, the second contact opening OP2, the first contact 100_1, the second contact 100_2, the first spacer 102_1, the second spacer 102_2, the substrate 104, and the device element 106 in FIG. 1B, respectively.

The example embodiments described in FIG. 4A may be configured the same as or (substantially) similar to the combination of features of the example embodiments described with reference to FIGS. 2A and 3A. For example, a height (a thickness) in the first direction of the contact 400 may be equal to a height (a thickness) in the first direction of the spacer 402. The example embodiments described in FIG. 4B may be configured the same as or (substantially) similar to the combination of features of the example embodiments described with reference to FIGS. 2B and 3B. For example, a height (a thickness) in the first direction of the second contact 400_2 may be equal to a height (a thickness) in the first direction of the second spacer 402_2.

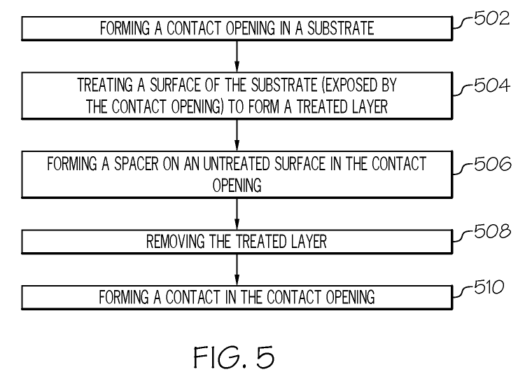

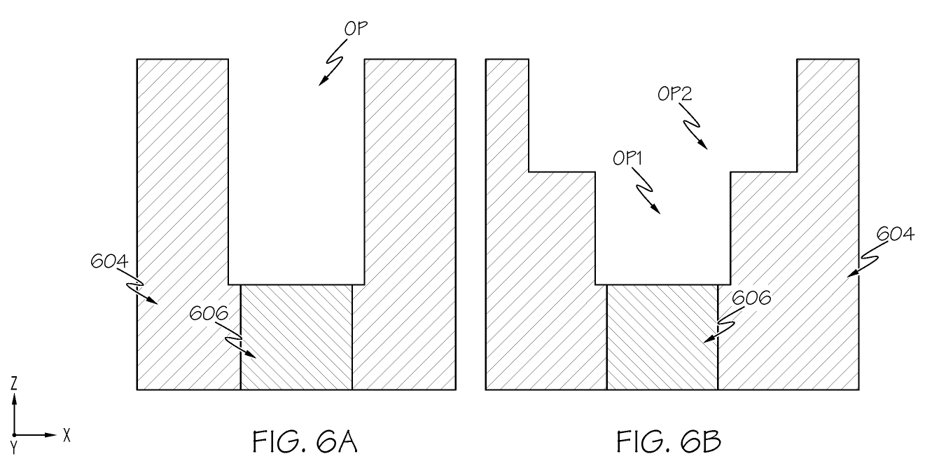

FIG. 5 is a flow chart of methods of forming an integrated circuit device according to some embodiments. FIGS. 6A, 6B, 7A, 7B, 8A, 8B, 9A, and 9B are cross-sectional views, illustrating methods of forming integrated circuit devices in FIGS. 3A and 3B according to some embodiments.

FIGS. 6A and 6B are cross-sectional views of an intermediate process, including forming a contact opening in a substrate. Referring to FIGS. 5, 6A, and 6B, the methods may include forming a contact opening OP (e.g., the contact opening OP in FIG. 6A and the first contact opening OP1 and the second contact opening OP2 in FIG. 6B) in a substrate 604 (Block 502). The opening OP may expose a portion of the substrate 604. For example, the forming the opening OP may expose a side surface and a lower surface of the substrate 604. The opening OP may expose, for example, an upper surface of the device element 606. The sidewall of the opening OP may be a side surface of the substrate 604. A lower end of the opening OP may be a lower surface of the substrate 604 (or an upper surface of the device element 606).

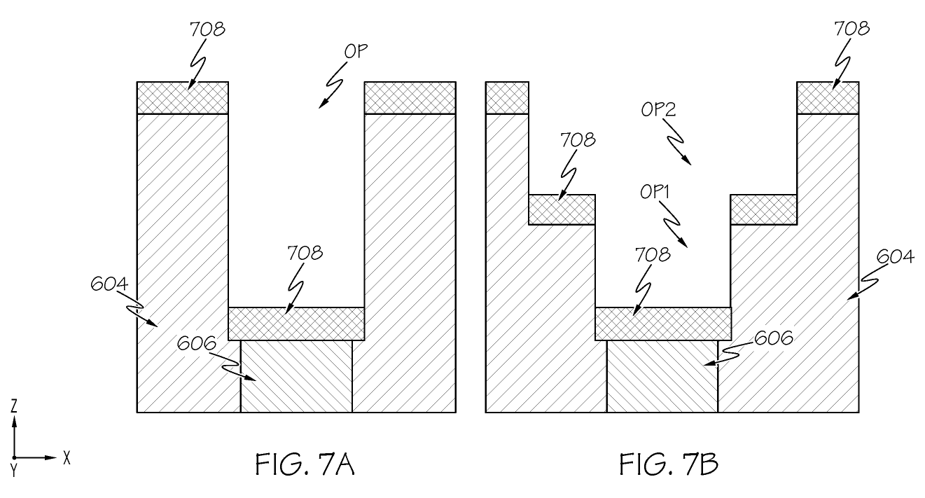

FIGS. 7A and 7B are cross-sectional views of an intermediate process, including treating a surface of a substrate (e.g., a surface of the substrate exposed by the contact opening) to form a treated layer. Referring to FIGS. 5, 7A, and 7B, the methods may include treating a surface of the substrate 604 (and/or a surface of the device element 606) exposed by the contact opening OP (e.g., the contact opening OP in FIG. 7A and the first contact opening OP1 and the second contact opening OP2 in FIG. 7B) (Block 504). In some embodiments, the lower surface of the substrate 604 exposed by the contact opening OP (e.g., the contact opening OP in FIG. 7A and the first contact opening OP1 and the second contact opening OP2 in FIG. 7B) may be treated. In some embodiments, an upper surface of the device element 606 exposed by the contact opening OP (e.g., the contact opening OP in FIG. 7A and the first contact opening OP1 in FIG. 7B) may be treated. In some embodiments, an upper surface (e.g., the top surface) of the substrate 604 may be treated.

The treating the surface of the substrate 604 (and/or the surface of the device element 606) may include a remote plasma treatment process, but the embodiments are not limited thereto. For example, the treating the surface of the substrate 604 (and/or the surface of the device element 606) may include oxidation, nitridation, and/or metallization thereof.

In some embodiments, a side surface of the substrate 604 exposed by the contact opening OP (e.g., the contact opening OP in FIG. 7A and the first contact opening OP1 and the second contact opening OP2 in FIG. 7B) may not be treated or may be substantially less treated than the lower surface of the substrate 604 (and/or the upper surface of the device element 606) exposed by the contact opening OP (e.g., the contact opening OP in FIG. 7A and the first contact opening OP1 and the second contact opening OP2 in FIG. 7B).

The treating a surface of the substrate 604 (and/or the device element 606) may form a treated layer 708 on the treated surface of the substrate 604 (and/or the treated surface of the device element 606). For example, the treated layer 708 may be formed on the lower surface of the substrate 604 (and/or the upper surface of the device element 606) exposed by (the lower end of) the contact opening OP (e.g., the contact opening OP in FIG. 7A and the first contact opening OP1 and the second contact opening OP2 in FIG. 7B). In some embodiments, the treated layer 708 may be formed on the upper surface (e.g., top surface) of the substrate 604.

In some embodiments, the treated layer 708 may have at least one material feature that is different that of the substrate 604 (and the device element 606). In some embodiments, the treated layer 708 may have a physical thickness in the first direction. In some embodiments, the treated layer 708 may not have a physical thickness in the first direction or may have a negligible thickness in the first direction.

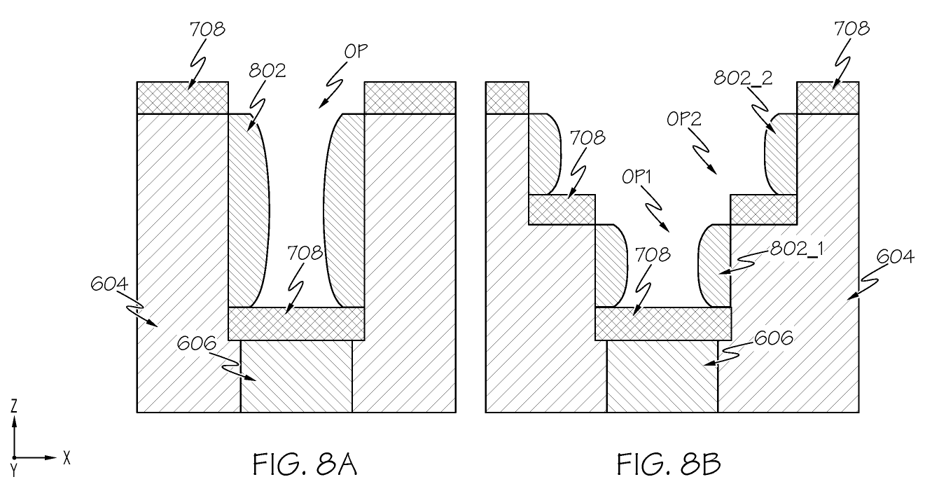

FIGS. 8A and 8B are cross-sectional views of an intermediate process, including forming a spacer on an untreated surface of the substrate (in the contact opening). Referring to FIGS. 5, 8A, and 8B, the methods may include forming a spacer 802 (e.g., a spacer 802 in FIG. 8A and a first spacer 802_1 and a second spacer 802_2 in FIG. 8B) on a sidewall of the contact opening OP (e.g., the contact opening OP in FIG. 8A and the first contact opening OP1 and the second contact opening OP2 in FIG. 8B) (Block 506). In some embodiments, the spacer 802 (e.g., the spacer 802 in FIG. 8A and the first spacer 802_1 and the second spacer 802_2 in FIG. 8B) may be formed on a side surface of the substrate 604 exposed by the contact opening OP (e.g., the contact opening OP in FIG. 8A and the first contact opening OP1 and the second contact opening OP2 in FIG. 8B). In some embodiments, the spacer 802 (e.g., the spacer 802 in FIG. 8A and the first spacer 802_1 and the second spacer 802_2 in FIG. 8B) may not be formed (may be substantially prevented from forming) on the treated layer 708. In some embodiments, the spacer 802 may be formed by a selective growth process. For example, the selective growth process may include a chemical vapor deposition (CVD), atomic layer deposition (ALD), plasma enhanced (PE) CVD, etc.

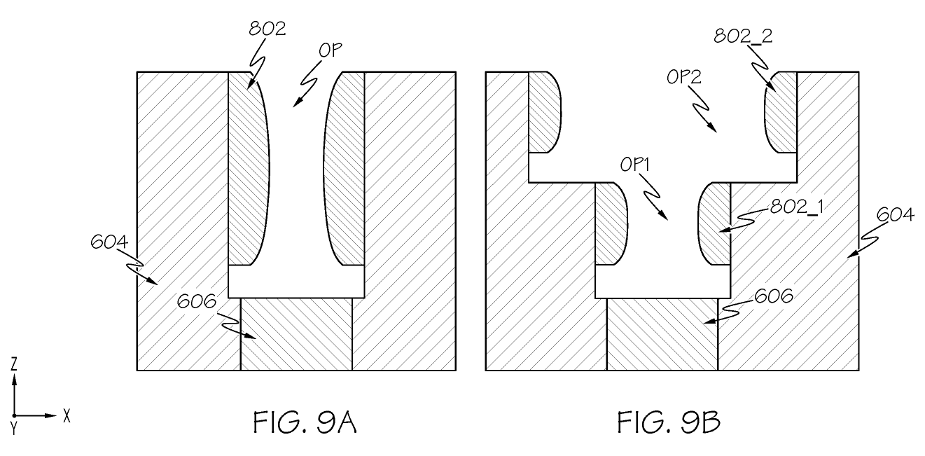

FIGS. 9A and 9B are cross-sectional views of an intermediate process, including removing the treated layer. Referring to FIGS. 5, 9A, and 9B, the methods may include removing the treated layer 708 (Block 508). In some embodiments, the removing the treated layer 708 may be omitted. For example, the removing the treated layer 708 may be omitted when the treated layer 708 does not have a physical thickness in the first direction or has a negligible physical thickness in the first direction.

Referring to FIGS, 5, 3A, 3B, 9A, and 9B the contact 300 (e.g., the contact 300 in FIG. 3A and the first contact 300_1 and the second contact 300_2 in FIG. 3B) may be formed in the contact opening OP (Block 510). For example, the contact 300 may at least partially fill the (a remnant) of the contact opening OP after the forming the spacer 302 (e.g., the first spacer 302 in FIG. 3A and the first spacer 302_1 and the second spacer 302_2 in FIG. 3B corresponding to the spacer 802 in FIG. 8A and the first spacer 802_1 and the second spacer 802_2 in FIG. 8B, respectively). The contact 300 may be on the spacer 302 in the contact opening OP.

Referring to FIGS. 1A, 1B, 2A, 2B, 3A, 3B, 4A, 4B, 7A, 7B, 8A, 8B, 9A, and 9B, the sizes and arrangements of the contact and the contact spacer may be controlled by controlling the height (the thickness) of the treated layer. For example, when the treated layer 708 has a substantial thickness in the first direction on the lower surface of the substrate 604 (and/or the upper surface of the device element 606) exposed by the contact opening OP as illustrated in FIG. 7A, the contact (e.g., the contact 100 in FIG. 1A and the contact 300 in FIG. 3A) may be positioned on a lower surface (a lower end) of the spacer (e.g., the spacer 102 in FIG. 1A and the spacer 302 in FIG. 3A) as described in FIGS. 1A and 3A. On the other hand, when the treated layer 708 does not have a thickness in the first direction or has a negligible thickness in the first direction on the lower surface of the substrate 604 (and/or the upper surface of the device element 606), the lower surface (the lower end) of the contact (e.g., the contact 200 in FIG. 2A and the contact 400 in FIG. 4A) may not be on the lower surface (the lower end) of the spacer (e.g., the spacer 202 in FIG. 2A and the spacer 402 in FIG. 4A) as described in FIGS. 2A and 4A.

Referring to FIGS. 1A, 1B, 2A, 2B, 3A, 3B, 4A, 4B, 7A, 7B, 8A, 8B, 9A, and 9B, the sizes and arrangements of the contact and the contact spacer may be controlled by performing a selective etch back process and/or a chemical mechanical polishing (planarization) (CMP) process after forming the contact in the contact opening. For example, when the selective etch back process and/or the CMP process is omitted or performed less, the contact (e.g., the contact 100 in FIG. 1A and the contact 200 in FIG. 2A) may be positioned (may remain) on the upper surface (the upper end) of the spacer (e.g., the spacer 102 in FIG. 1A and the spacer 202 in FIG. 2A) as described in FIGS. 1A and 2A. On the other hand, when the selective etch back process and/or the CMP process is performed more, the contact (e.g., the contact 300 in FIG. 3A and the contact 400 in FIG. 4A) may not be positioned on the upper surface (the upper end) of the spacer (e.g., the spacer 302 in FIG. 3A and the spacer 402 in FIG. 4A) as described in FIGS. 3A and 4A. For example, when the selective etch back process and/or the CMP process is performed more, the upper surface (the upper end) of the contact (e.g., the contact 300 in FIG. 3A and the contact 400 in FIG. 4A) may be coplanar with the upper surface (the upper end) of the spacer (e.g., the spacer 302 in FIG. 3A and the spacer 402 in FIG. 4A) as described in FIGS. 3A and 4A.

FIG. 10 is a cross-sectional view an integrated circuit device 1000 according to some embodiments. The integrated circuit device 1000 may include a gate structure 1200, a source/drain (S/D) region 1400, and a first contact structure 1600. The first contact structure 1600 may be electrically connected to (may be in contact with) the gate structure 1200. The first contact structure 1600 may be the same as or (substantially) similar to the example embodiments described above (with reference to FIGS. 1A, 2A, 3A, and 4A). However, the embodiments are not limited thereto. For example, the first contact structure 1600 may be electrically connected to (may be in contact with) the S/D region 1400. In some embodiments, the first contact structure 1600 may be positioned on a lower side of the gate structure 1200 and/or the S/D region 1400.

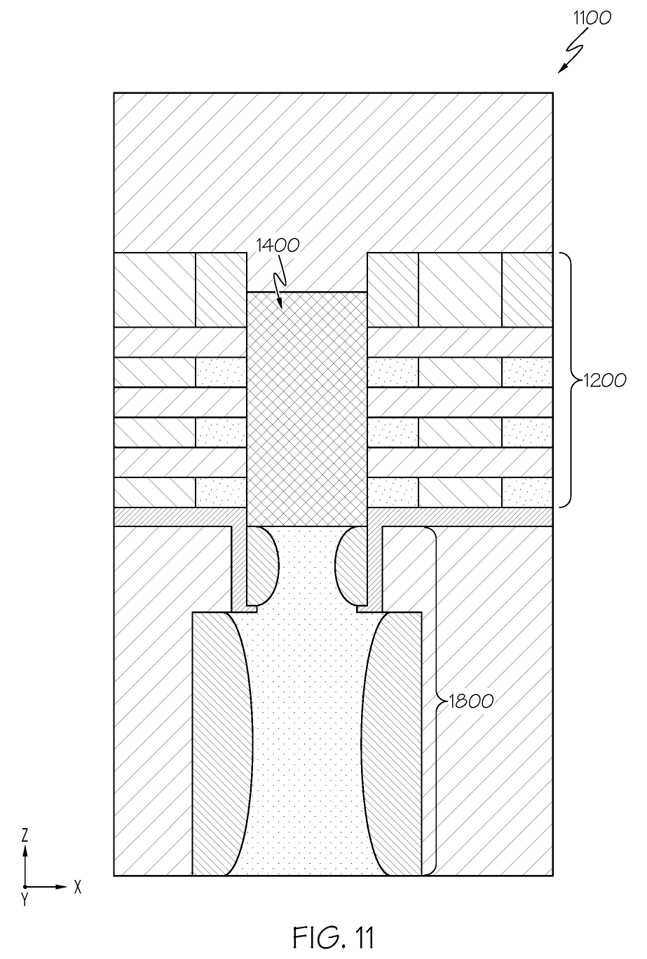

FIG. 11 is a cross-sectional view an integrated circuit device 1100 according to some embodiments. The integrated circuit device 1100 may include a gate structure 1200, a source/drain (S/D) region 1400, and a second contact structure 1800. The second contact structure 1800 may be electrically connected to (may be in contact with) the S/D region 1400. The second contact structure 1800 may be the same as or (substantially) similar to the example embodiments described above (with reference to FIGS. 1B, 2B, 3B, and 4B). However, the embodiments are not limited thereto. For example, the second contact structure 1800 may be electrically connected to (may be in contact with) the gate structure 1200. In some embodiments, the second contact structure 1800 may be positioned on an upper side of the gate structure 1200 and/or the S/D region 1400.

Example embodiments described herein show that a width of an upper portion of a contact (e.g., the third width W3 of the third portion of the contact 100 in FIG. 1A) may be easily adjusted (controlled) by controlling the degree of the selective etch back process and/or the degree of the CMP process after forming the contact in the contact opening. As a result, the CD of the contacts may be improved (reduced) as short circuit between (the upper portions of) the contacts can be prevented (reduced) by controlling the degree of the selective etch back process and/or the degree of the CMP process. The spacer, which includes an insulating material, in the contact opening may provide additional protection from short circuits between the contacts. In addition, as a width of a lower portion of the contact (e.g., the first width W1 of the first portion of the contact 100 in FIG. 1A) may be greater than a width of a middle portion of the contact (e.g., the second width W2 of the second portion of the contact 100 in FIG. 1A), the resistance of the contact may be reduced. The profile of the contact described herein (e.g., an hourglass shape in a cross-sectional view) may reduce (e.g., prevent) the deformation of the upper portion of the contact and residue or air gap (seam or void) in the contact. Example embodiments described herein may improve the electrical features, such as reliability and operation speed, by controlling (improving) the profile of the contact.

Example embodiments are described herein with reference to the accompanying drawings. Many different forms and embodiments are possible without deviating from the spirit and teachings of this disclosure and so the disclosure should not be construed as limited to the example embodiments set forth herein. Rather, these example embodiments are provided so that this disclosure will be thorough and complete and will convey the scope of the disclosure to those skilled in the art. In the drawings, the sizes and relative sizes of layers and regions may be exaggerated for clarity. Like reference numbers refer to like elements throughout.

Example embodiments of the present inventive concept are described herein with reference to cross-sectional views or plan views that are schematic illustrations of idealized embodiments and intermediate structures of example embodiments. As such, variations from the shapes of the illustrations as a result, for example, of manufacturing techniques and/or tolerances, are to be expected. Thus, example embodiments of the present inventive concept should not be construed as limited to the particular shapes illustrated herein but include deviations in shapes that result, for example, from manufacturing.

Unless otherwise defined, all terms (including technical and scientific terms) used herein have the same meaning as commonly understood by one of ordinary skill in the art to which the present inventive concept belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

The terminology used herein is for the purpose of describing particular embodiments only and is not intended to be limiting of the present inventive concept. As used herein, the singular forms "a," "an" and "the" are intended to include the plural forms as well, unless the context clearly indicates otherwise. It will be further understood that the terms "comprises," "comprising," "includes" and/or "including," when used in this specification, specify the presence of the stated features, steps, operations, elements and/or components, but do not preclude the presence or addition of one or more other features, steps, operations, elements, components and/or groups thereof. As used herein the term "and/or" includes any and all combinations of one or more of the associated listed items.

It will be understood that when an element is referred to as being "coupled," "connected," or "responsive" to, or "on," another element, it can be directly coupled, connected, or responsive to, or on, the other element, or intervening elements may also be present. In contrast, when an element is referred to as being "directly coupled," "directly connected," or "directly responsive" to, or "directly on," another element, there are no intervening elements present. As used herein, the term "and/or" includes any and all combinations of one or more of the associated listed items. Moreover, the symbol "/" (e.g., when used in the term "source/drain") will be understood to be equivalent to the term "and/or."

It will be understood that although the terms "first," "second," etc. may be used herein to describe various elements, these elements should not be limited by these terms. These terms are only used to distinguish one element from another. Thus, a first element could be termed a second element without departing from the teachings of the present embodiments.

Many different embodiments have been disclosed herein, in connection with the above description and the drawings. It will be understood that it would be unduly repetitious and obfuscating to literally describe and illustrate every combination and subcombination of these embodiments. Accordingly, the present specification, including the drawings, shall be construed to constitute a complete written description of all combinations and subcombinations of the embodiments described herein, and of the manner and process of making and using them, and shall support claims to any such combination or subcombination.

It should be noted that in some alternate implementations, the functions/acts noted in flowchart blocks herein may occur out of the order noted in the flowcharts. For example, two blocks shown in succession may in fact be executed substantially concurrently or the blocks may sometimes be executed in the reverse order, depending upon the functionality/acts involved. Moreover, the functionality of a given block of the flowcharts and/or block diagrams may be separated into multiple blocks and/or the functionality of two or more blocks of the flowcharts and/or block diagrams may be at least partially integrated. Finally, other blocks may be added/inserted between the blocks that are illustrated, and/or blocks/operations may be omitted without departing from the scope of the present inventive concept. The above-disclosed subject matter is to be considered illustrative, and not restrictive, and the appended claims are intended to cover all such modifications, enhancements, and other embodiments, which fall within the scope of the inventive concept. Thus, to the maximum extent allowed by law, the scope is to be determined by the broadest permissible interpretation of the following claims and their equivalents, and shall not be restricted or limited by the foregoing detailed description.

What is claimed is:

1. An integrated circuit device comprising:
a substrate that has a contact opening; and
a contact in the contact opening,
wherein a first portion of the contact has a first width in a first direction that is parallel with an upper surface of the substrate,
wherein a second portion of the contact has a second width in the first direction,
wherein a third portion of the contact has a third width in the first direction,
wherein the second portion of the contact is between the first portion of the contact and the third portion of the contact in a second direction that is perpendicular to the upper surface of the substrate,
wherein at least one of the first width and the third width is greater than the second width, and
wherein another of the first width and the third width is equal to or greater than the second width.

2. The integrated circuit device of claim 1 further comprising: a spacer on a sidewall of the contact opening in the substrate.

3. The integrated circuit device of claim 2, wherein a first portion of the spacer has a fourth width in the first direction,
wherein a second portion of the spacer has a fifth width in the first direction,
wherein a third portion of the spacer has a sixth width in the first direction,
wherein the second portion of the spacer is between the first portion of the spacer and the third portion of the spacer in the second direction,
wherein at least one of the fourth width and the sixth width is less than the fifth width, and
wherein another of the fourth width and the sixth width is equal to or less than the fifth width.

4. The integrated circuit device of claim 3, wherein the contact is on an upper surface of the spacer.

5. The integrated circuit device of claim 4, wherein the contact is on a lower surface of the spacer.

6. The integrated circuit device of claim 4, wherein a lower surface of the contact is coplanar with a lower surface of the spacer.

7. The integrated circuit device of claim 3, wherein an upper surface of the contact is coplanar with an upper surface of the spacer.

8. The integrated circuit device of claim 7, wherein the upper surface of the spacer is coplanar with the upper surface of the substrate.

9. The integrated circuit device of claim 7, wherein a lower surface of the contact is coplanar with a lower surface of the spacer.

10. The integrated circuit device of claim 3, wherein the spacer has a convex shape that protrudes from the sidewall of the contact opening in the substrate in the first direction.

11. The integrated circuit device of claim 1, wherein a width of an upper end of the contact opening in the first direction is equal to the third width.

12. An integrated circuit device comprising:
a substrate that has a contact opening;
spacers on sidewalls of the contact opening in the substrate in a cross-sectional view, wherein the spacers are spaced apart from each other in a first direction that is parallel with an upper surface of the substrate; and
a contact between the spacers in the first direction,
wherein first portions of the spacers are spaced apart from each other at a first distance in the first direction,
wherein second portions of the spacers are spaced apart from each other at a second distance in the first direction, and
wherein third portions of the spacers are spaced apart from each other at a third distance in the first direction,
wherein the second portions are between the first portions and the third portions in a second direction that is perpendicular to the upper surface of the substrate,
wherein at least one of the first distance and the third distance is greater than the second distance, and
wherein another of the first distance and the third distance is equal to or greater than the second distance.

13. The integrated circuit device of claim 12, wherein the spacers are mirror-symmetric to each other in the first direction.

14. The integrated circuit device of claim 12, wherein the contact is on upper surfaces and lower surfaces of the spacers.

15. The integrated circuit device of claim 12, wherein an upper surface of the contact is coplanar with upper surfaces of the spacers.

16. The integrated circuit device of claim 12, wherein a lower surface of the contact is coplanar with lower surfaces of the spacers.

17. The integrated circuit device of claim 12, wherein a thickness of the contact is equal to a thickness of each of the spacers in the second direction.

18. A method of forming an integrated circuit device, the method comprising:
forming a contact opening in a substrate, the contact opening having opposing sidewalls and a lower end therebetween;
performing a surface treatment on the lower end of the contact opening;
forming a spacer on at least one of the opposing sidewalls of the contact opening; and
forming a contact on the spacer in the contact opening,
wherein the forming the spacer comprises a selective growth on a side surface of the substrate exposed by the contact opening.

19. The method of claim 18, wherein the performing the surface treatment comprises a remote plasma treatment that changes at least one material characteristic of a lower surface of the substrate exposed by the contact opening, and
wherein the at least one material characteristic of the lower surface of the substrate exposed by the contact opening differs from that of the side surface of the substrate exposed by the contact opening.

20. The method of claim 18, wherein a first portion of the contact has a first width in a first direction that is parallel with an upper surface of the substrate,
wherein a second portion of the contact has a second width in the first direction,
wherein a third portion of the contact has a third width in the first direction,
wherein the second portion of the contact is between the first portion of the contact and the third portion of the contact in a second direction that is perpendicular to the upper surface of the substrate,
wherein at least one of the first width and the third width is greater than the second width, and
wherein another of the first width and the third width in equal to or greater than the second width.
